(19) United States
(12) Patent Application Publication
(10) Pub. No.: US 2003/0019973 A1
(43) Pub. Date: Jan. 30, 2003

(54) Thread guiding element

(75) Inventor: Jorg Krumeich, Winterthur (CH)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sulzer Markets and Technology AG, Winterthur (CH)

(21) Appl. No.: 10/199,297

(22) Filed: Jul. 19, 2002

(30) Foreign Application Priority Data
Jul. 26, 2001 (EP) 01810738.3

(51) Int. Cl. C23C 14/32; B65H 16/02

(52) U.S. Cl. 242/570; 204/192.16

(57) ABSTRACT

Thread guiding element for the guidance of threads, in which a surface of the body (3) of the thread guiding element is provided, at least in the region in which the thread (8) is guided, with a surface coating (5) which has a structure which is formed as a matrix for the reception of a lubricant and/or of a sliding agent.

The invention relates to a thread guiding element and to a method for coating a surface of a thread guiding element in accordance with the preamble of the independent claim of the respective category.

Numerous components in textile machines which are in contact with threads which are guided at high speed are subject to exceptional stresses through frictional forces. In the context of this application, components of textile machines which are in contact with guided threads and/or are intended for guiding threads are designated as thread guiding elements. In this the term thread will in the following comprise in addition to textile threads, which consist of various materials such as for example wool, cotton or silk, also yarns or twines such as e.g. paper yarns, cellulose yarns or synthetic yarns of perlon, nylon, dralon or other synthetic materials, as well as threads in the broadest sense, i.e. for example also wires of glass, metal or other materials. Particularly high frictional forces arise at those points at which the thread is pressed with great force against the corresponding thread guiding element. If the thread is also guided at high speed, this can result in the liberation of considerable amounts of heat as a result of frictional losses. The negative consequences of the described frictional effects gain dramatically in significance in particular when a very large number of thread guiding elements are in thermal contact with one another in the most constricted space. This leads on the whole to intolerable temperature increases both of the thread itself and of the thread guiding element and of system or machine components which are in contact with it. A corresponding temperature increase in conjunction with the associated temperature gradients in the material can lead to deformations of the thread guiding element and/or of other system or machine components involved and can in some cases also result in damage to the guided thread through direct or indirect effects of the various frictional mechanisms. Moreover, it should be noted that the as a rule aggressive abrasion behavior of the thread in conjunction with the discussed frictional effects rapidly leads to a massive mechanical wear of the thread guiding element. The described effects then ultimately lead in many cases to a premature wear of the components involved.

In order to reduce the wear which is caused by the frictional mechanisms, embodiments of thread guiding elements are known which are manufactured completely of ceramic materials. The disadvantage of thread guiding elements of this kind consists on the one hand in that a considerable cost and complexity is required in the manufacturing process in order to be able to conform precisely to the required geometrical error tolerances; on the other hand, ceramics show in principle significantly poorer properties of thermal conductivity in comparison with metals, so that the frictional heat which is produced during operation can only be insufficiently dissipated.

On the other hand, thread guiding elements are also known which are manufactured completely of metal. The surfaces of thread guiding elements of this kind are then frequently hardened using special processes in order to reduce the wear on the relatively soft metallic body. The precise true to size manufacture of thread guiding elements of this kind is admittedly ensured technically and economically, but in spite of the hardened surfaces the proneness to wear is still significantly greater in comparison with the thread guiding elements which are manufactured of ceramic materials. Moreover, it is known that hardened surfaces of this kind as a rule show a high resistance with respect to the accumulation and/or embedding of foreign components. This means in particular that lubricants and/or sliding agents which are carried along by the thread or are fed in in other ways can either not at all or only insufficiently accumulate at and/or in the surface of the thread guiding element. In this it is precisely these effects that are frequently desirable, since the possibility of developing an additional sliding and/or lubricating film between the thread and the surface of the thread guiding element thereby exists, which can additionally reduce the relevant frictional coefficients and thus drastically reduce both the production of frictional heat and the mechanical wear of the thread and system components through friction.

The object of the invention is therefore to develop an improved thread guiding element, which reduces the frictional forces between the guided thread and the thread guiding element to a minimum, through which the frictionally caused wear of the thread guiding element is substantially prevented and therefore the working life is massively increased, and which, moreover, can be mass produced economically and with the highest precision.

The subjects of the invention which satisfy these objects in regard to method and apparatus are characterised by the features of the independent claim of the respective category.

The respective subordinate claims relate to particularly advantageous embodiments of the invention.

The thread guiding element in accordance with the invention for the guidance of threads is characterized in that a surface of the body of the thread guiding element is provided, at least in the region in which the thread is guided, with a surface coating which has a structure which is formed as a matrix for the taking up of a lubricant and/or of a sliding agent.

A thin film of this kind consisting of a lubricant and/or of a sliding agent between the thread and the surface coating of the thread guiding element leads to the friction between the thread and the thread guiding element being reduced to a considerable extent. Not only is the mechanical wear of the thread, of the thread guiding element and of the system or machine components which are in contact with them reduced during operation, but also the production of frictional heat is further reduced. The lifetime of the thread guiding element and the system or machine components which are in contact with it is thus significantly increased and the cloth quality is significantly improved. The residual heat which unavoidably arises as a result of a not completely vanishing coefficient of friction for the friction between the thread and the thread guiding element is reliably dissipated as a result of the good thermal conductivity properties of the thread guiding element in accordance with the invention.

The method in accordance with the invention for the coating of a thread guiding element produces on the surface of the body of the thread guiding element, at least in that region in which the thread is guided, a surface coating which has a structure which is formed as a matrix for the taking up of a lubricant and/or of a sliding agent.

The surfaces of thread guiding elements can be treated in different manners and are frequently completely or partly provided with surface coatings consisting of the most varied of materials. These surface coatings are preferably used in the region of chemically, thermally or mechanically highly stressed locations of the worked article and have as a rule the task of reducing the proneness to wear through mechanical stressing or corrosion and thus of increasing the lifetime of the worked article.

An entire series of different methods for the application of surface coatings, which can be based on entirely different principles, is known. Thus for example methods for the surface alloying of a base metal by means of high energy beams such as laser or electron beams are well known, with the melted surface of the base metal being alloyed with the alloy metal. The application of additional new surface coatings, for example by means of thermal spraying methods, through plasma spraying or electrodeless immersion methods, are also known techniques.

In this the problem of maintaining the dimensions of the treated worked article is very frequently a central point, which restricts the possibilities of using different coating techniques or can in the special case completely prohibit them. It is not seldom for the thickness of the applied layers to be outside acceptable tolerances as a result of the process, so that the coated worked article must be post-processed mechanically or chemically in laborious processes. In particular for the coating of metallic worked articles or worked articles of plastic, for the case that the maintaining of the dimensions of the worked article must be ensured with high precision, there exist methods which thermally stress the worked article only little even during the coating process and moreover produce very thin surface layers with thicknesses in the range of a few microns.

In the following a shed holder element such as is used in series shed weaving machines will be described as a preferred exemplary embodiment of a thread guiding element for the guidance of threads, in which a surface of the body of the thread guiding element is provided at least in the region in which the thread is guided with a surface coating which has a structure which is formed as a matrix for the reception of a lubricant and/or of a sliding agent; and a suitable method for producing a thin ceramic surface coating will be given. In this a thread guiding element can also be specifically designed in other shapes, e.g. as a ring, an eye, a roll, a comb, a groove or in another manner.

The invention will be explained in more detail with reference to the drawings. Shown are:

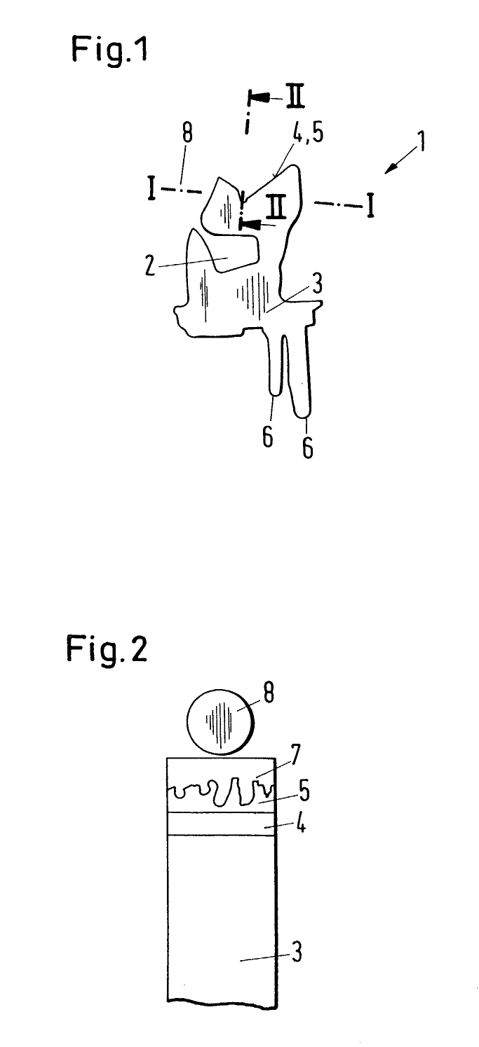

FIG. 1 a schematic illustration of a shed holder element having an integrated weft insertion passage for use in the weaving rotor of a series shed weaving machine,

FIG. 2 a section through a part of a surface coated shed holder element in accordance with FIG. 1 along the section line II-II,

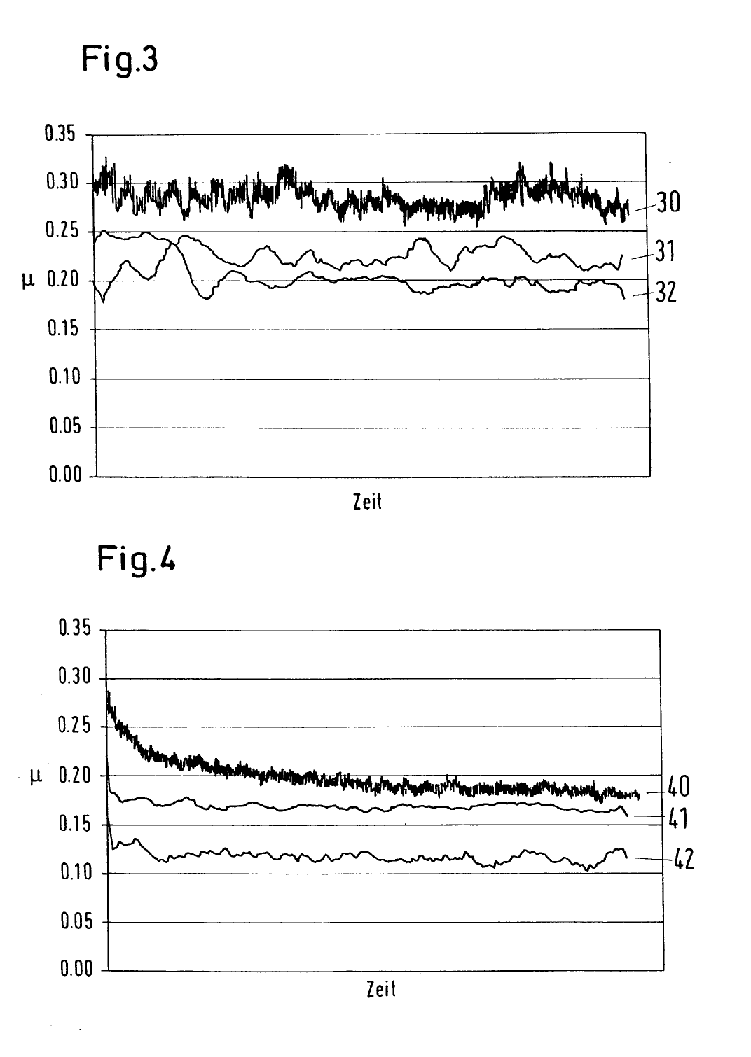

FIG. 3 coefficient of friction μ in dependence on the time for sized threads consisting of different materials in the use of conventional uncoated shed holder elements,

FIG. 4 as FIG. 3, but for shed holder elements in accordance with the invention.

FIG. 1 shows in a schematic illustration a shed holder element 1 in accordance with the invention for a series shed weaving machine. The body 3 of the shed holder element 1, which is made of a metal, is completely or partly provided with a ceramic surface coating 5 and is anchored in the weaving rotor by pins 6. For the formation of a shed the warp thread 8 is guided during operation through the shed holder element 1 perpendicular to the section line II-II along the direction I-I over the coated surface of the shed holder element 1. The weft thread is guided through the weft insertion passage 2 perpendicularly to the plane spanned by the section line II-II and the direction I-I.

FIG. 2 shows the same shed holder element 1 in a section along the section line II-II, with additional layers and a warp thread 8 being illustrated.

Series shed weaving machines are multiple phase weaving machines in which a plurality of stepwise mutually displaced weft threads are inserted into rotating sheds, with the weaving warp being guided via a weaving rotor, the continual rotation of which represents an essential constituent of the shed forming. In this the complete shed forming takes place through the cooperation of a plurality of functional elements. On the rotor itself, these are substantially the shed holder elements 1 with integrated weft insertion passage 2 and the beat-up combs. Up to a total of 10,000 shed holder elements 1 are arranged in comb-like manner in the axial direction in a plurality of rows on the surface along the periphery of the weaving rotor. In the cooperation of the rotor curvature and the rotor movement, the shed holder elements 1 open the sheds, which are arranged one behind the other. In this arrangement the warp threads 8 are positioned through a suitable apparatus in such a manner that when lifted by a shed holder element 1 they either form the upper shed or remain in the lower shed position.

In the preferred exemplary embodiment which is shown in FIG. 1, the shed holder element 1 comprises a body 3 which is bounded by a boundary layer 4. It is known that the boundary layers 4 of the shed holder elements are carbonitrided in order to achieve a hardening of the surfaces and thereby to reduce the wear through friction. An essential disadvantage of the carbonitriding however consists in that treated boundary layers 4 of this kind show a high resistance to the accumulation and/or embedding of materials at and/or in the surface.

In the use of the known shed holder elements in series shed weaving machines, considerable frictional forces arise at the contact locations between the warp thread 8 and the shed holder element, the magnitude of which shows additional large fluctuations in dependence on time, which is reflected among other things in the time dependent behavior of the associated coefficient of friction (see FIG. 3). Caused by the high frequency of rotation of the weaving rotor and the forces with which the warp threads 8 are pressed against the shed holder element, in particular during the building up of the shed, considerable amounts of heat are produced between the warp thread 8 and the surface of the shed holder element through the arising frictional forces. The negative consequences of the described frictional effects gain dramatically in importance through the fact that up to a total of 10,000 shed holder elements are mounted on a single weaving rotor and are in good thermal contact with one another via the weaving rotor. The temperature increase which accompanies the heat production can, among other things, lead to a deformation of the weaving rotor and to damage to the warp thread 8 through diverse frictional mechanisms. This is particularly true of glass threads, so that the manufacture of high quality glass meshes is not possible using the shed holder elements which have previously been in use. The consequence of this is that the weaving speed of series shed weaving machines is limited primarily by the friction between the warp thread 8 and the shed holder element.

The preferred exemplary embodiment of the shed holder element 1 in accordance with the invention with an integrated weft insertion passage 2 in accordance with FIG. 1 and FIG. 2 consists of a body 3 which is manufactured of a metal and which has a boundary layer 4 which consists of the same material as the body 3 itself and at least one additional ceramic surface coating 5. The boundary layer 4 of the metallic body 3 of the shed holder element 1 is carbonitrided. Carbonitriding is understood to mean a special kind of surface treatment of a metallic thread guiding element. In this the surface layers of the thread guiding element are enriched with carbon and nitrogen in a thermo-chemical process. An at most ten micron thick coating 5, consisting of a ceramic material, is applied to the carbonitrided boundary layer 4 of the shed holder element 1 through deposition from the gaseous phase. The method of sputtering, which will be explained in the following, is preferably used as a special method for the coating. Titanium oxide is used as the preferable coating material. For the coating of the boundary layers 4 of the shed holder element 1, highly pure titanium is liberated from a titanium target in a vacuum chamber in the presence of oxygen. The oxygen is taken up by the titanium in a chemical reaction, with the stoichiometry of the arising titanium oxide compounds being determined by the partial pressure of the oxygen. The thus arising titanium oxide compounds then deposit on the boundary layer 4 of the shed holder element 1, which is likewise located in the vacuum chamber together with the titanium target, and form a surface coating 5 of a specific uniform thickness in dependence on the duration of the reaction. The particular advantages of sputtering in comparison with other coating methods consist among other things in the low deposition temperature and in the possibility of producing uniform thin layers with controlled stoichiometry in the micron range. Laborious post processing of the layers through mechanical or chemical processes is not necessary. In this the ceramic surface which is applied during the process of sputtering has a structure which is formed as a matrix which is suitable for the reception of a lubricant and/or of a sliding agent, so that the lubricant and/or sliding agent can be deposited on and/or embedded in this structure, which is formed in a matrix-like manner.

In the processing of the warp thread 8 in textile machines the warp thread 8 is as a general rule not processed in the dry state, but rather is impregnated for various reasons with a mixture of different components which also has, among other properties, certain lubricating and/or sliding properties. The mixture of different components is generally designated as a size. The size is carried along by the warp thread 8 during the processing and can accumulate at the points of contact between the warp thread 8 and the shed holder element 1 at the sputtered on surface 5 of the shed holder element 1. In this it is not necessary for the thread to carry along the size backing to the shed holder element 1. Rather, the size can also be applied onto the surface of the shed holder element 1 by special, possibly additional, apparatuses. During operation a thin stable film 7 consisting of size develops after a short start-up time between the coated surface 5 of the shed holder element 1 and the warp thread 8, which is impregnated with the size. In cooperation with the relatively high air humidity of approximately 70%-80%, as is typically set in the vicinity of the weaving rotor of a series shed weaving machine, the thin size film 7 leads to a significant lowering of the coefficient of friction μ. FIG. 3 illustrates the temporal development of the coefficient of friction μ as was measured for coated threads 8 of different materials in the use of the conventional uncoated shed holder elements. The corresponding measurement curves for threads of glass 30, cotton 31 and polyester 32 are shown by way of example in FIG. 3. The measured coefficients of friction μ display values on the order of magnitude of μ≈0.20-0.30 and are distinguished by strong fluctuations of the value of the coefficient of friction μ in dependence on time. These fluctuations of the coefficient of friction μ lead to corresponding fluctuations in the mechanical tension in the warp thread 8. In contrast with this, FIG. 4 shows the results of analogous measurements of the coefficient of friction μ for glass 40, cotton 41 and polyester 42 which were achieved when using the shed holder element 1 in accordance with the invention, which was coated with titanium oxide In all threads which were studied the coefficient of friction μ already drops off massively after a short time to values which lie about 30% lower than in the uncoated shed holder elements, which is to be attributed to the development of the mentioned thin size film 7 on the ceramic surface coating 5 of the shed holder element 1 (see FIG. 4). Moreover, the value of the coefficient of friction μ remains significantly more stable in time, which means that the fluctuations of the mechanical tensions in the warp thread 8 are reduced to a considerable extent and thus the warp thread 8 is substantially more carefully treated. Through the reduction of the frictional forces and the significantly reduced production of heat which is associated therewith, the choice of materials which come under consideration as substrate material for the body of the shed holder element 1 in accordance with the invention is also significantly broadened. Thus in addition to metallic or ceramic substrate materials, plastics such as poly ether ether ketone (PEEK), polyamide (PA) or various filled plastics (composites) also certainly come under consideration. Finally, the massive reduction of the frictional forces between the warp thread 8 and the shed holder element 1 leads to the electrical drive which is used for driving the weaving rotor showing a lower power consumption, which thus leads to the saving of electrical energy.

1. Thread guiding element for the guidance of threads, characterized in that a surface of the body (3) of the thread guiding element is provided, at least in the region in which the thread (8) is guided, with a surface coating (5) which has a structure which is formed as a matrix for the taking up of a lubricant and/or of a sliding agent.

2. Thread guiding element in accordance with claim 1, comprising a surface coating (5) of ceramic material which has a thickness of less than ten microns.

3. Thread guiding element in accordance with claim 1 or claim 2, comprising a body (3) consisting of metal which has a thermal conductivity of at least 20 W·m⁻¹·K⁻¹ or comprising a body (3) consisting of plastic, such as for example poly ether ether ketone (PEEK) or polyamide (PA), or comprising a body (3) consisting of a filled plastic (composite).

4. Thread guiding element in accordance with any one of the claims 1 to 3, as a shed holder element (1) for a weaving rotor of a series shed weaving machine.

5. Weaving rotor of a series shed weaving machine comprising a shed holder element (1) in accordance with claim 4.

6. Series shed weaving machine comprising a weaving rotor in accordance with claim 5.

7. Method for the coating of a thread guiding element in accordance with any one of the claims 1 to 4, characterized in that a surface of the body (3) of the thread guiding element is provided, at least in that region in which the thread (8) is guided, with a surface coating (5) which has a structure which is formed as a matrix for the reception of a lubricant and/or of a sliding agent.

8. Method for the coating of surfaces of thread guiding elements in accordance with claim 7 by means of deposition from the gaseous phase through sputtering.

9. Method in accordance with claim 7 or claim 8, with a ceramic which preferably comprises titanium oxide being used for the surface coating (5).

10. Shed holder element (1) for rotors in series shed weaving machines, comprising a surface coating (5) which is produced in accordance with a method in accordance with any one of the claims 7 to 9 and which has a thickness of less than ten microns.
